(19) United States
(12) Patent Application Publication
(10) Pub. No.: US 2024/0372470 A1
(43) Pub. Date: Nov. 7, 2024

(54) COMPOSITE MULTI-MATERIAL ELECTROMECHANICAL ENERGY STORAGE COMPONENT FOR POWER CONVERSION

(71) Applicant: Massachusetts Institute of Technology, Cambridge, MA (US)

(72) Inventors: Jeffrey H. Lang, Sudbury, MA (US); David J. Perreault, Cambridge, MA (US); Jessica Boles, Murfreesboro, TN (US); Joseph Bonavia, Millbrae, CA (US)

(73) Assignee: Massachusetts Institute of Technology, Cambridge, MA (US)

(21) Appl. No.: 18/685,983

(22) PCT Filed: Oct. 5, 2022
(86) PCT No.: PCT/US2022/045750

§ 371 Date: Feb. 23, 2024

Related U.S. Application Data
(60) Provisional application No. 63/252,333, filed on Oct. 5, 2021.

(51) Int. Cl. H02M 3/158; H10N 30/50; H10N 30/87

(52) U.S. Cl. CPC H02M 3/158; H10N 30/50; H10N 30/87

(57) ABSTRACT

According to one aspect of the present disclosure, an electrical-to-electrical power converter includes an energy storage component including a transducer material and a second material for mechanical energy storage, the second material attached to the transducer material. In some embodiments, the transducer material and the second material are both configured to store mechanical energy.

### CROSS-REFERENCE TO RELATED APPLICATIONS

This application claims the benefit under 35 U.S.C. § 119 of U.S. Provisional Patent Application No. 63/252,333 filed on Oct. 5, 2021, which is hereby incorporated by reference herein in its entirety.

### BACKGROUND

As the demand for smaller, lighter power electronics increases, commonly used magnetic components are pushed towards their physical limits for miniaturization. This motivates investigation into alternative passive components for use in power converters. Piezoelectric resonators (PRs) and associated converter topologies offer a promising alternative to conventional power conversion circuits for miniaturized settings. Figures of merit (FOMs) have been established for the selection of PR vibration modes and materials best suited for high efficiency, high power density power conversion applications. PRs alone (so-called “bare” PRs) offer favorable scaling properties for miniaturization when compared with magnetic components.

### SUMMARY

In view of the above, and in accordance with the concepts, structures, and techniques described, it is recognized that it would be advantageous to further reduce the footprint, volume, and mass of piezoelectric resonators (PRs). Described herein are multi-material electromechanical component design strategies that can be applied, according to some embodiments, to provide PR “augmentation.” As described herein, PR augmentation involves attaching or otherwise coupling an additional mass or compliant material to a PR to further increase its efficiency, power density, and energy handling density capabilities. In so doing, a composite electromechanical energy storage component can be realized that provides mechanical energy storage (and at least in some embodiments, significant mechanical energy storage) in multiple materials and in so doing achieves a higher storage density and better utilization of the capability of a piezoelectric material than is achievable with a piezoelectric resonator alone. Described herein are the effects of PR augmentation on several FOMs. A description is also provided to illustrate the extents to which the relative magnitudes of the augmentations can be increased before other limits prevent further augmentation, or further augmentation becomes detrimental to performance and size. Also described is an illustrative design of a mass-augmented PR, according to some embodiments. It is shown that this multi-material electromechanical energy storage component is capable of decreased loss and increased power densities by a factor of two or more.

According to one aspect of the present disclosure, an electrical-to-electrical power converter can include an energy storage component including a transducer material and a second material for mechanical energy storage, the second material attached to the transducer material.

In some embodiments, the energy storage component is an electromechanical resonator. In some embodiments, the transducer material has electrodes coupled to one or more of its surfaces. In some embodiments, the second material is attached at least one of the more surfaces to which the electrodes are coupled. In some embodiments, the second material is attached to one or more surfaces of the transducer material different from the one or more surfaces to which the electrodes are coupled. In some embodiments, the energy storage component is a single-port device. In some embodiments, the energy storage component is a multi-port device. In some embodiments, the transducer material includes a piezoelectric material.

In some embodiments, the transducer material and the second material are both configured to store mechanical energy. In some embodiments, the mechanical energy stored by the second material is at least 10% of total mechanical energy stored by the energy storage component. In some embodiments, the mechanical energy stored by the second material is primarily kinetic energy. In some embodiments, the second material comprises a high-mass-density material. In some embodiments, the high-mass-density material includes at least one of: tungsten, gold, platinum, lead, or uranium.

In some embodiments, the second material is configured to enable the converter to operate near one or more physical limits, such as stress limits, strain limits, electric field limits, and loss density limits. In some embodiments, the second material has a volume which is greater than or equal to a volume of the transducer material. In some embodiments, the second material has a volume which is less than a volume of the transducer material. In some embodiments, all or part of the second material has a density greater than or equal to that of the transducer material. In some embodiments, the second material includes multiple distributed layers. In some embodiments, the multiple distributed layers of the second material have substantially identical geometries and material compositions. In some embodiments, the second material includes a patterned material structure comprising a mesh pattern or a backbone-and-rib pattern. In some embodiments, all or part of the second material spans an entire surface of the transducer material. In some embodiments, all or part of the second material may be electrically insulative. In some embodiments, the second material is configured to provide an acoustic wave boundary. In some embodiments,

In some embodiments, the transducer material has first and second electrodes on first and second opposing planar surfaces of the transducer material. In some embodiments, the second material includes a first mass layer attached to the first electrode. In some embodiments, the second material includes a second mass layer attached to the second electrode. In some embodiments, the transducer material, the first mass layer, and the second mass layer are all configured to store mechanical energy during operation of the converter. In some embodiments, the transducer material includes a piezoelectric resonator (PR).

In some embodiments, the transducer material is configured to have a length extensional vibration mode. In some embodiments, the transducer material is configured to have a thickness shear vibration mode. In some embodiments, the transducer material is configured to have a thickness extensional vibration mode. In some embodiments, the transducer material is configured to have a contour extensional vibration mode. In some embodiments, the transducer material is configured to have a radial vibration mode. In some embodiments, the transducer material has at least four surfaces (e.g., planar surfaces) with electrodes coupled to two of the at least four surfaces. In some embodiments, the second material is attached to at least one of the at least four surfaces to which the electrodes are coupled. In some embodiments, the second material is attached to at least one of the at least four surfaces different from those to which the electrodes are coupled.

According to another aspect of the present disclosure, an energy storage component for a power converter can include: a piezoelectric resonator (PR) having first and second electrodes on first and second opposing planar surfaces of the PR; a first mass layer attached to the first electrode; and a second mass layer attached to the second electrode, wherein the PR, the first mass layer, and the second mass layer are all configured to store mechanical energy during operation of the PR. In some embodiments, the PR is configured to have a thickness extensional vibration mode.

According to another aspect of the present disclosure, a power converter having an input and an output can include: an energy storage component including a transducer material and a second material attached thereto, the transducer material and the second material both being configured to store mechanical energy; and a plurality of switches configured to transfer energy from the converter input to the converter output via the energy storage component. The energy storage component may include any of the previously mentioned embodiments.

It should be appreciated that individual elements of different embodiments described herein may be combined to form other embodiments not specifically set forth above. Various elements, which are described in the context of a single embodiment, may also be provided separately or in any suitable sub-combination. It should also be appreciated that other embodiments not specifically described herein are also within the scope of the following claims.

### BRIEF DESCRIPTION OF THE DRAWINGS

The manner of making and using the disclosed subject matter may be appreciated by reference to the detailed description in connection with the drawings, in which like reference numerals identify like elements.

FIG. 1 is a block diagram of a system including a dc-dc converter within which a composite multi-material electromechanical energy storage component may be used, according to some embodiments.

FIG. 1A is a block diagram of another system within which a composite multi-material electromechanical energy storage component may be used, according to some embodiments.

FIG. 2 is a circuit diagram showing an example of a switching topology that can be used within the system of FIG. 1 or 1A, according to some embodiments.

FIG. 3 is a schematic diagram of a thickness extensional vibration mode of a bare PR.

FIG. 4 is a Butterworth-Van Dyke (BVD) equivalent circuit model for PRs.

FIG. 5 is a plot of a bare PR's impedance in the proximity of a vibration mode.

FIG. 6 is a schematic diagram of a thickness extensional vibration mode of a mass-augmented PR, according to some embodiments.

FIG. 7 is a circuit diagram of an equivalent circuit model for a mass-augmented PR, according to some embodiments.

FIG. 8 is a plot illustrating impedance shift due to mass augmentation of a PR, according to some embodiments.

FIG. 9 is a plot showing how a mass-augmented PR can have the effect of shifting resonant and anti-resonant frequencies downward, according to some embodiments.

FIG. 10 is a plot showing how a mass-augmented PR can scale a maximum-efficiency operating point, according to some embodiments.

FIG. 11 is a plot showing mechanical efficiency that can be achieved using a mass-augmented PR, according to some embodiments.

FIG. 12A is a plot showing stress-limited maximum dimensionless current amplitude that can be exhibited using a mass-augmented PR, according to some embodiments.

FIG. 12B is a plot showing strain-limited maximum dimensionless current amplitude that can be exhibited using a mass-augmented PR, according to some embodiments.

FIG. 12C is a plot showing electric field-limited maximum dimensionless current amplitude that can be exhibited using a mass-augmented PR, according to some embodiments.

FIG. 13A is a plot showing loss-limited volumetric energy handling that can be exhibited using a mass-augmented PR, according to some embodiments.

FIG. 13B is a plot showing stress-limited volumetric energy handling that can be exhibited using a mass-augmented PR, according to some embodiments.

FIG. 13B is a plot showing stress-limited volumetric energy handling that can be exhibited using a mass-augmented PR, according to some embodiments.

FIG. 13C is a plot showing strain-limited volumetric energy handling that can be exhibited using a mass-augmented PR, according to some embodiments.

FIG. 13D is a plot showing electric field-limited volumetric energy handling that can be exhibited using a mass-augmented PR, according to some embodiments.

FIG. 14A is a plot showing loss-limited areal power density be exhibited using a mass-augmented PR, according to some embodiments.

FIG. 14B is a plot showing stress-limited areal power density be exhibited using a mass-augmented PR, according to some embodiments.

FIG. 14C is a plot showing strain-limited areal power density be exhibited using a mass-augmented PR, according to some embodiments.

FIG. 14D is a plot showing electric field-limited areal power density be exhibited using a mass-augmented PR, according to some embodiments.

FIG. 15A is an impedance plot of a non-augmented PR and the approximated and non-approximated mass-augmented equivalent, according to some embodiments, without tangent approximation.

FIG. 15B is an impedance plot of a non-augmented PR and the approximated and non-approximated mass-augmented equivalent, according to some embodiments, with tangent approximation.

The drawings are not necessarily to scale, or inclusive of all elements of a component/system, emphasis instead generally being placed upon illustrating the concepts, structures, and techniques sought to be protected herein.

### DETAILED DESCRIPTION

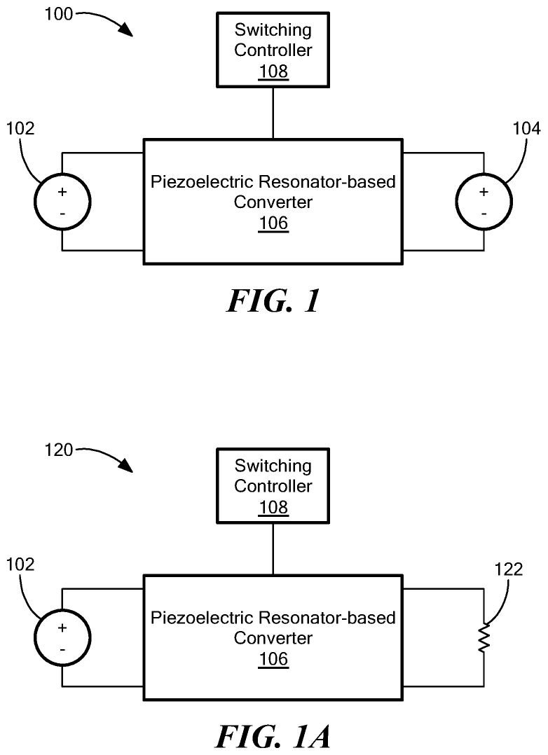

Referring to FIG. 1, an illustrative system 100 can include an input voltage 102, an output voltage 104, a dc-dc converter 106 disposed between the input and output voltages, and a switching controller 108, according to some embodiments. Output voltage 104 may correspond to a voltage source load. Converter may be provided as a step-up or step-down converter.

Converter 106 can include one or more piezoelectric resonators (PRs) and one or more switches arranged in given topology to selectively couple the input and output voltages 102, 104 to the PR electrodes. The one or more PRs may comprise all, or substantially all, of the energy transfer components of converter 106. For example, converter 106 may not include any capacitors, magnetics, or other energy storage components other than the one or more PRs. Thus, converter 106 may be referred to as a “PR-based” converter. The one or more PRs can include at least one mass-augmented PR according to the present disclosure.

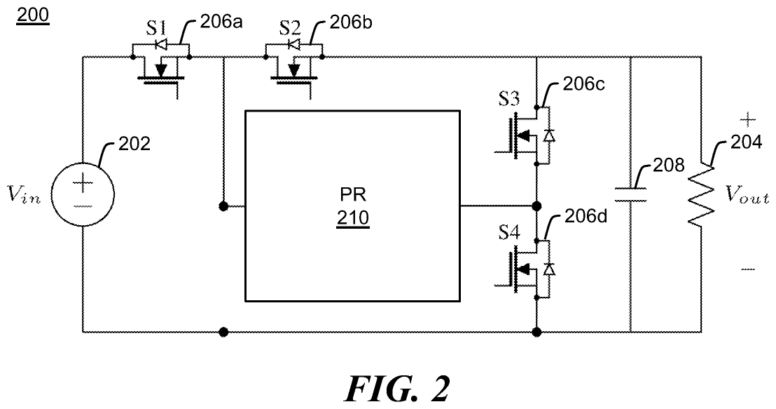

An example of topology that can be used within converter 106 is shown and described in the context of FIG. 2. Other topologies that can be used are described in U.S. Pat. Pub. No. 2022/0200449, entitled “DC-DC Converter Based On Piezoelectric Resonator” and published on Jun. 23, 2022. In some embodiments, the negative terminal of input voltage 102 may be coupled to the negative terminal of output voltage 104 (i.e., system 100 may be a common-negative system).

Switching controller 108 can include hardware and/or software configured to control switches within converter 106 according to one or more switching sequences. A switching sequence can be selected to provide low-loss soft charging of the PR capacitance. Examples of switching sequences that can be used are described in U.S. Pat. Pub. No. 2022/0200449. In some embodiments, controller 108 can be provided as an application specific integrated circuit (ASIC).

Referring to FIG. 1A, according to another embodiment, a system 120 can include a PR-based converter 106 coupled between an input voltage 102 and a resistive load 122. That is, embodiments of the PR-based converters disclosed herein can be used within systems having voltage source loads, as in FIG. 1, and within systems having resistive loads, as in FIG. 1A.

While power converters based on PRs have been described, the structures and techniques disclosed herein can also be used to provide improved piezoelectric transformers (PTs) and may be employed within PT-based converters, such as those described in PCT Pat. App. No. PCT/US2022/036325 filed on Jul. 7, 2022. More generally, disclosed structures and techniques can be employed within both single-port devices and multi-port devices.

FIG. 2 shows an example of a switching topology 200 that can be used within the system 100 of FIG. 1 and/or system 120 of FIG. 1A, according to some embodiments. The illustrative topology 200 includes an input voltage 202, an output voltage 204, four switches 206a-206d (S1-S4), a capacitor 208, and a PR. The components can be connected as shown in FIG. 2. The switches 206a-206b can be controlled to provide low-loss soft charging of the PR 210 capacitance, such as by using a high-efficiency switching sequence described in U.S. Pat. Pub. No. 2022/0200449. For example, the Vᵢₙ-Vₒᵤₜ, Zero, Vₒᵤₜ switching sequence may be used.

PR 210 can be provided as a mass-augmented PR according to the present disclosure. Switching topology 200 of FIG. 2 is merely one example of a topology within which a mass-augmented PR may be employed and is not meant to be limiting.

### Piezoelectric-Based Power Conversion

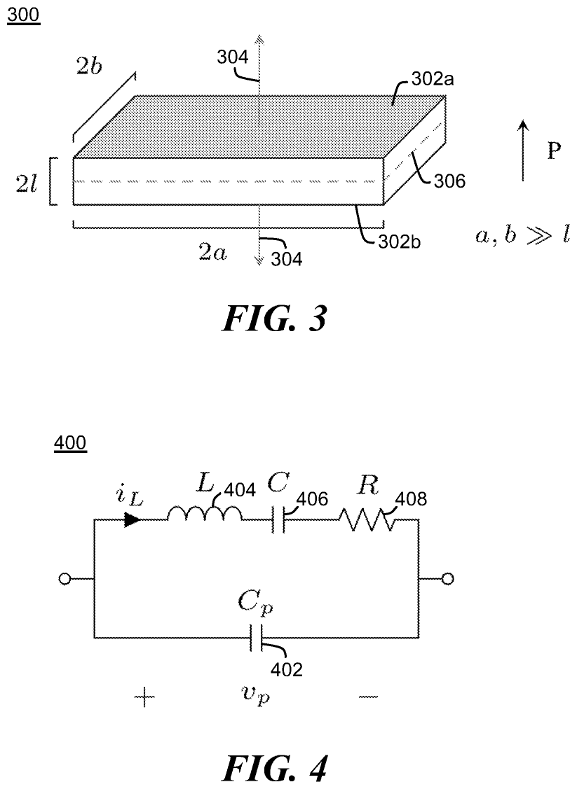

FIG. 3 is a schematic diagram of a thickness extensional vibration mode of a bare PR 300, as is known in the art. PR 300 is configured to have electrodes 302a, 302b on opposing planar surfaces (or “plates”), as shown. The polarization direction of the PR 300 is denoted with “P” in the figure, and each electrode is assumed to have area 4ab with distance 21 between electrodes, with a, b>>l. In the figure, displacement direction is marked with arrows 304 and the nodal plane marked with dashed line 306. For the purpose of this disclosure, all surfaces are assumed to have no externally-applied stress (i.e., all surfaces are traction-free), and the origin is assumed to be at the PR's center. For material property tensors, it should be noted that the x₃ direction corresponds to the polarization axis.

According to embodiments of the present disclosure, a thickness extensional vibration mode can be used in conjunction with a mass-augmented PR. However, the concepts, structures, and techniques disclosed herein can also be used in conjunction with other vibration modes, such as any of the modes shown and described in PCT Pat. App. No. PCT/US2022/028043, entitled “Piezoelectric Resonators For Power Conversion” and filed on May 6, 2022.

FIG. 4 shows a Butterworth-Van Dyke (BVD) equivalent circuit model 400 for a PR. The model 400 includes the PR's physical electrical input capacitance 402 (Cₚ) and an LCR branch including an inductor (L) 404, a capacitor (C) 406, and a resistor (R) 408 to model the PR's electromechanical resonance properties. In the case of an ideal, resistor 408 (R) may be omitted.

FOMs and design methodologies have been established for PRs in power conversion. The definitions and forms of these FOMs are summarized next.

### Free End Model and Boundary Conditions

For the purpose of discussion, excitation of purely the fundamental resonant frequency of the thickness extensional vibration mode can be assumed. In this mode, a PR must always satisfy the following constitutive equations and equation of motion, with parameters defined in Tables 1 and 2:

$${T}_{3} = {c}_{33}^{D} \frac{\partial {u}_{3}}{\partial {x}_{3}} - {e}_{33} {E}_{3} {D}_{3} = {e}_{33} \frac{\partial {u}_{3}}{\partial {x}_{3}} + {ϵ}_{33}^{S} {E}_{3} \frac{\partial {T}_{3}}{\partial {x}_{3}} = \frac{{\partial }^{2} {u}_{3}}{\partial {t}^{2}} \qquad ( 1 )$$

TABLE 1
Material State Definitions

| | |
|---|---|
| u | Mechanical Displacement (m) |
| T | Mechanical Stress (N/m²) |
| S | Mechanical Strain |
| E | Electric Field Strength (N/m) |
| D | Electric Flux Density (C/m²) |

TABLE 2
Material Property Definitions

| | |
|---|---|
| Qₘ | Mechanical Quality Factor |
| k | Electromechanical Coupling Factor |
| vₐ | Acoustic Velocity (m/s) |
| ρ | Mass Density (kg/m³) |
| ε | Dielectric Constant (F/m) |
| s | Compliance Constant (m²/N) |
| d | Piezoelectric Charge Constant (C/N) |
| c | Elastic Modulus (N/m²) |
| e | Piezoelectric Strain Modulus (C/m²) |
| σ | Poisson's Ratio |
| Tₘₐₓ | Maximum Mechanical Stress (N/m²) |
| Sₘₐₓ | Maximum Mechanical Strain |
| Eₘₐₓ | Max. Electric Field Strength (N/m) |

The subscript “3” in equation (1) and other equations provided herein refers to the three-direction as used in the art of continuum mechanics (and according to Voight notation) and corresponds to the polarization direction.

Assuming pure excitation of the fundamental mode, a wave solution of the form can also be assumed:

$${u}_{3} ( {x}_{3} , t ) = Δ sin ( κ {x}_{3} ) {e}^{j ω t} \qquad ( 2 )$$

for the displacement within the PR, where K is the wave number, and ω is the frequency of vibrations, related by:

$$ω = {v}_{a} κ = \frac{f}{2 π} {v}_{a} = \sqrt{\frac{{c}_{33}^{D}}{ρ}} \qquad ( 3 )$$

where vₐ is the PR material's acoustic velocity in m/s and f is the frequency of vibrations in Hz. By inserting (2) into (1) and enforcing the traction-free boundary condition

$${T}_{3} ( {x}_{3} = l ) = 0 \qquad ( 4 )$$

one can solve for the forms of state variables u, T, E, and D. By integrating D and E, one can find the form of the voltage, vₚ, and current, i_{L}, through the PR, and from them the form of the PR's electrical impedance. After approximating a tangent term with the first term of its partial fraction expansion, one can then set the impedance directly equal to the impedance of the BVD electrical model shown in FIG. 4. From this one can retrieve the values of L, C, Cₚ, and R in Table 3.

TABLE 3
Butterworth-Van Dyke Electrical Model Component Values

| Cₚ | C | L | R |
|---|---|---|---|
| ${ϵ}_{33}^{S} \frac{2 ab}{l}$ | $\frac{8 {C}_{p} {k}_{t}^{2}}{{γ}_{0}^{2}}$ | $\frac{{l}^{2}}{2 {C}_{p} {k}_{t}^{2} {v}_{a}^{2}}$ | $\frac{1}{4 {Q}_{M}} \frac{l {γ}_{0}}{{C}_{p} {k}_{t}^{2} {v}_{a}}$ |

$where {k}_{t}^{2} = \frac{{e}_{33}^{2}}{{c}_{33}^{D} {ϵ}_{33}^{S}} and {γ}_{0} = \sqrt{{π}^{2} - 8 {k}_{t}^{2}}$

TABLE 4
PR Power Conversion FOM

| | FOM_{M} | FOM_{APD} | FOM_{VEHD} |
|---|---|---|---|
| Definition | ${( \frac{{P}_{loss}}{{P}_{out}} )}^{- 1}$ | $\frac{{P}_{out}}{4 ab}$ | $\frac{{P}_{out}}{f ( 8 abl )}$ |
| Value | $4 {Q}_{M} \frac{{k}_{t}^{2}}{π {κ}_{0} {γ}_{0}}$ | $\frac{{I}_{L 0 , max}^{2}}{π {κ}_{0} {ϵ}_{33}^{S} {v}_{a}}$ | $\frac{{I}_{L 0 , max}^{2}}{{κ}_{0}^{2} {ϵ}_{33}^{S} {v}_{a}^{2}}$ |

where κ₀ is the dimensionless wave number κl, Pₗₒₛₛ is the PR’s loss density, and Pₒᵤₜ is converter power level.

### Figures of Merit

Table 4 includes the mathematical definitions and forms of the FOMs described in PCT Pat. App. No. PCT/US2022/028043. In particular, a mechanical efficiency FOM (FOM_{M}), an areal power density FOM (FOM_{APD}) and a volumetric energy handling density FOM (FOM_{VEHD}). The mechanical efficiency FOM is taken to be the inverse of the ratio of the power dissipated in the PR Pₗₒₛₛ (due to mechanical interactions) to the power delivered to the load Pₒᵤₜ. The areal power density FOM is taken to be the areal power density itself, that is Pₒᵤₜ divided by the electrode area, 4ab. Finally, the volumetric energy handling density is taken to be the energy delivered to the load during one cycle, divided by the volume of the PR, 8abl (assuming the geometry of FIG. 3).

The areal power density and volumetric energy handling densities depend on the geometry-normalized maximum amplitude of resonance I_{L0,max}:

$${I}_{L 0 , max} = \sqrt{\frac{2}{{R}_{o}} {( \frac{{P}_{loss}}{{A}_{s}} )}_{max}}$$

where a loss-per-surface-area-limited design is assumed.

These maximum values may likewise be based on the physical limits of the PR material (failure stress, breakdown voltage, etc.) or other practical limits on the system (heat dissipation capabilities, layer bonding strength, etc.). The lowest of these values limits power density, as this is considered the first point of failure in the system. Table 5 contains the values of I_{L0,max} associated with likely causes for PR failure: stress (T), strain (S), electric field (or E-field, E), and loss density (LD).

TABLE 5
Geometry-Normalized Maximum Current Amplitudes

| I_{L0,max}^{T} | I_{L0,max}^{S} | I_{L0,max}^{E} | I_{L0,max}^{LD} |
|---|---|---|---|
| $\frac{{e}_{33} {v}_{a}}{{c}_{33}^{D}} cot ( \frac{{κ}_{0}}{2} ) {T}_{max}$ | e₃₃νₐsin(κ₀)Sₘₐₓ | ${k}_{t}^{2} {ϵ}_{33}^{S} \frac{sin ( κ l )}{cos ( {κ}_{0} ) - {k}_{t}^{2}} {v}_{a} {E}_{max}$ | $\sqrt{4 {Q}_{M} \frac{{ϵ}_{33}^{S} {k}_{t}^{2} {v}_{a}}{{γ}_{0}} {LD}_{max}}$ |

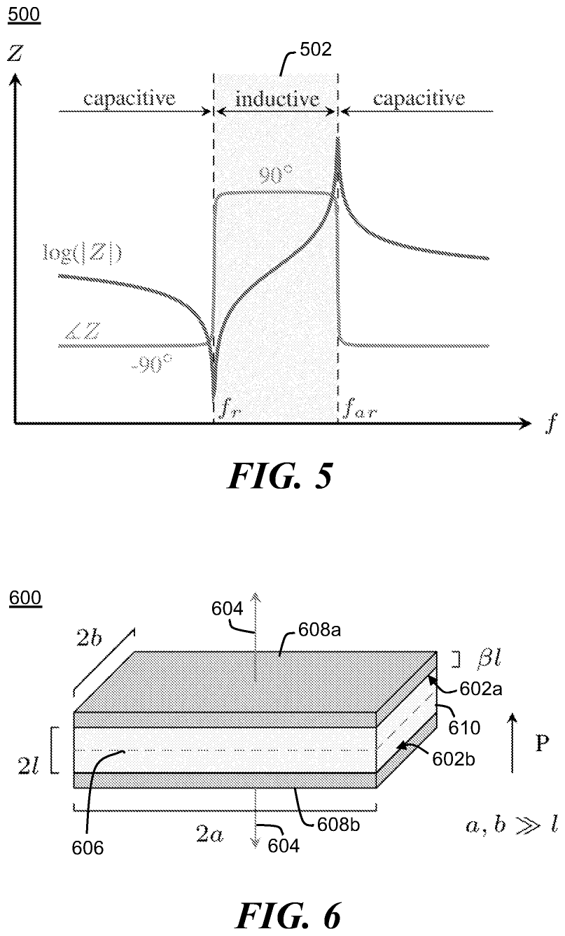

FIG. 5 is a plot 500 showing a bare PR's impedance in the proximity of a vibration mode, where fᵣ is the resonant frequency and fₐᵣ is the anti-resonant frequency. The inductive region 502 between the resonant and anti-resonant frequency may be of most interest to power conversion.

### Mass-Augmented Piezoelectric Resonator Model

Turning to FIG. 6, to illustrate the effects of PR augmentation to form a composite electromechanical energy storage element, an example of a mass-augmented PR 600, according to some embodiments, is shown. In contrast to existing bare PRs, mass-augmented PR 600 of FIG. 6 has a second material for mechanical energy storage attached to the PR material (or “transducer material”) 610. In more detail, and in the vibration mode configuration shown, mass layers 608a and 608b may be added to electrodes 602a and 602b on opposing planar surfaces of the PR material 610, respectively. In some embodiments, mass layers 608a, 608b may be electrically conductive and may form part of electrodes 602a, 602b. In other embodiments, mass layers 608a, 608b may be separate from electrodes 602a, 602b (e.g., physically separate or electrically isolated therefrom). Each of the mass layers 608a, 608b (608 generally) can have a mass of density ρₘ, thickness βl, and an area 4ab. Transducer material 610 can have an area 4ab and distance 21 between the electrodes 602a, 602b, as shown.

In some embodiments, transducer material 610 can comprise lead zirconate titanate (PZT). Mass layers 608 can include a non-piezoelectric material, such as Tungsten. Other materials that may be used within mass layers 608 are discussed below. Also described below are different techniques for manufacturing a mass-augmented PR such as the one shown in FIG. 6, including design parameters that may be used to select the geometry of mass-augmented PR 600 (see, e.g., Table 7 below).

While two mass layers 608a, 608b are shown in the embodiment of FIG. 6, in other embodiments a single mass layer or more than two mass layers may be added to the transducer material 610. In some embodiments, a mass layer 608 can have an area that is different from that of the transducer material 610 to which it is attached. For example, a mass layer 608 can have a larger or smaller area. In some embodiments, and as shown in FIG. 6, mass layers 608 can span substantially the entire surface of the transducer material 610. In the example of FIG. 6, the edges of mass layers 608 are shown to be aligned with the edges of transducer material 610. In other embodiments, one or more edges of mass layers 608 may be extend past one or more edges of transducer material 610 or may be patterned to be narrower than the width of the electrode and/or transducer material 610.

The illustrative mass-augmented PR 600 of FIG. 6 is configured to have a thickness extensional vibration mode. In the figure, displacement direction is marked with arrows 604 and the nodal plane marked with dashed line 606. As previously discussed, the structures and techniques disclosed herein can be used in conjunction with other vibration modes. For example, a mass-augmented PR can also be configured to have a length extensional, thickness shear, contour extensional, or radial vibration mode, which modes are shown and discussed in PCT Pat. App. No. PCT/US2022/028043). In these cases, the mass may be attached to surfaces that are different than the electrode surfaces. As one example, the transducer material can have six surfaces (e.g., planar surfaces), with electrodes coupled to two of the surfaces and the second material for mechanical energy storage attached to one or more of the surfaces (e.g., the same surfaces as the electrodes, or different surfaces). This is merely an example and not meant to be limiting to the structures and techniques sought to be protected herein.

The additional mass layers 608 can be modeled point masses attached to the free ends of the PR (x₃=l and x₃=−l), and thus enforce the boundary condition:

$${T}_{3} ( {x}_{3} = l ) = - \frac{{{m}_{added} \ddot{u}}_{}}{4 a b} = - {ρ}_{M} β l \frac{{\partial }^{2} u}{\partial {t}^{2}} \qquad ( 5 )$$

in place of (4) (which comes directly from Newton's Second Law for a point mass).

In general, a composite energy storage element/component according to the present disclosure can includes layers of: a transducer material (e.g., transducer material 610 in FIG. 6), such as a piezoelectric material; a second mass- and/or compliance-adding material for mechanical energy storage (e.g., mass layers 608 in FIG. 6); and electrodes to couple electrical energy in and out of the structure (e.g., electrodes 602a, 602b in FIG. 6). In addition, there may be other layers to facilitate fabrication or operation such as seed layers (for plating), adhesion layers (for deposition and bonding), etc. For rigid boundaries and/or on-chip fabrication, acoustic Bragg reflectors may be used for reduced-loss wave reflection at the component's boundaries.

The second material may be implemented as a single lumped piece or multiple distributed layers. In the case of multiple distributed layers (or “pieces”), the different layers can have substantially similar geometries (e.g., shapes and sizes) and material compositions, or can have different geometries and material compositions. The second material, electrode, and/or an additional material may be likewise implemented as a pattern (e.g., a mesh pattern, a backbone-and-rib pattern, etc.) to (a) suppress motion in undesired directions, (b) reduce undesired loss, and/or (c) provide for multi-port elements. Other surfaces of the second material may be fixed (advantageous for added compliance) or unfixed (advantageous for added mass). Further, if the second material is electrically conductive, it may be utilized as the electrode itself. The second material may act as an acoustic wave boundary, as assumed in the analysis above, or as a wave-carrying medium, which is analyzed in below.

Irrespective of solid or patterned layers, and according to embodiments of the present disclosure, one or more of the following stackups may be used, where “transducer” is the transducer material (e.g., piezoelectric) and “material” is the second added material acting as mass/compliance:
Electrode-transducer-electrode-material
Electrode-transducer-material-electrode
Material-electrode-transducer-electrode-material
Material-transducer-material (if material is electrically conductive)
Electrode-transducer-transducer-electrode-material
Electrode-transducer-transducer-material-electrode
Material-electrode-transducer-transducer-electrode-material
Material-transducer-transducer-material (if material is electrically conductive)
   for which each of these stackups may be optionally terminated with rigid boundarie(s) (i.e., Bragg reflectors) or left to be traction-free. Also, each of these stackups may be serially repeated for a multi-layer device. Analysis described herein may assume the second material to be attached in two solid layers on opposite faces of the piezoelectric material, each spanning the entire face, such as illustrated in FIG. 6.

It should be noted that the resulting component may act as a single-port device (e.g., a piezoelectric resonator) or a multi-port device (e.g., a piezoelectric transformer).

A variety of materials may be used within a composite energy storage element, according to the present disclosure. Piezoelectric materials for the transducer element include PZT, lithium niobate, barium titanate, zinc oxide, aluminum nitride, bismuth titanate, lead metaniobate, lead magnesium niobate, and lead titanate. In particular, PZT and lithium niobate have been found to have high FOMs for power conversion, as described herein. However, it is important to note that a transducer material having a low FOM does not necessarily preclude it from utility in a composite energy storage element. If the density of the material is low enough, mass augmentation may improve its performance to an extent that makes it competitive with PZT and lithium niobate. One example for which this may be true is aluminum nitride, which is a fully-CMOS-compatible front-end-of-line material that could be easily integrated into a chip fabrication. Augmenting aluminum nitride with mass may improve its efficiency and power density capabilities enough such that the economics of its fabrication outweigh those of PZT and lithium niobate.

In some embodiments, a composite energy storage component may have a second attached material configured (e.g., in terms of material selection and/or geometry) to storage at least a certain percentage of the stored mechanical energy of the component. For example, the second added material may be configured to store at least 10%, 15%, or 25% of the stored mechanical energy of the component. In some embodiments, the mechanical energy stored by the second material is primarily kinetic energy (i.e., more than 50% of the energy stored by the second attached material may be kinetic energy).

For mass augmentation, it is recognized herein that stiff and dense (in comparison to the transducer material) added mass is desirable. The second material may include a high-mass-density material such as tungsten, gold, platinum, lead, or uranium. As used herein, the term “high-mass-density material” refers to a material (e.g., mass layer) that has a density greater than or equal to that of transducer material to which it is attached. Tungsten in particular is used widely within the MEMS community for adding mass thanks to its high density and reasonable cost. Further, materials that do not introduce significant loss in the case of internal wave propagation may also be advantageous. In some cases, the second attached material can be electrically insulative. Adhesion or seed layers may consist of tungsten, chrome, or aluminum, among others.

A composite energy storage element according to the present disclosure may be fabricated using a variety of processes familiar to the MEMS community. These include electroplating (electroplating a conductive mass element over the electrode, or electroless plating followed by electroplating), evaporation, sputtering, spin-on sol-gel processing, photolithography, reactive ion etching, chemical etching, sintering, and bonding. Tungsten in particular is commonly electroplated for thick layers (greater than 1-10 um), and for thinner layers, chemical vapor deposition, sputtering, or evaporation may be used.

Sputtering and spin-on sol-gel processing may be used for PZT deposition, though these techniques tend to be limited to thicknesses of up to tens of microns (beyond this thickness, they tend to crack due to internal stress). For thicker PZT layers, bonding may be used. Bonded PZT can be fired (sintered) and shaped off chip before bonding. Deposited PZT can be fired and shaped on chip. Once deposited, PZT can be etched wet (chemically) and dry (reactive ion plasma).

For metals, sputtering, evaporation, and electroplating may be used. Some metals naturally adhere to substrate, while others require an adhesion layer. Front-end-of-line metals (i.e., materials used at the beginning of fabrication) can include, for example, Aluminum. Towards the back-end-of-line, Tungsten and Titanium are also used. Out of line deposition of Gold, Silver, Copper and Platinum (and many others) is also possible.

In some embodiments, patterning (etching) at all levels can be guided by photolithography using masks. In some cases, liftoff for very thin films may be used.

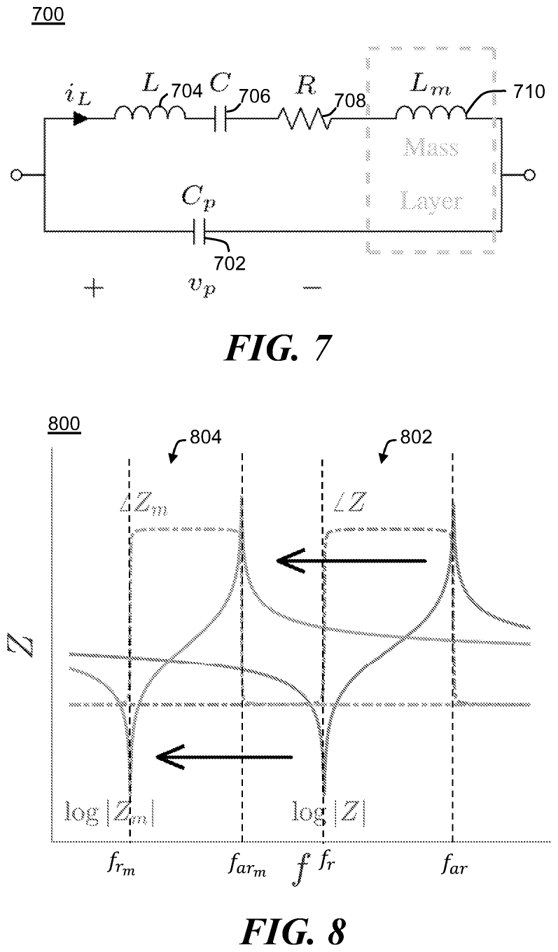

FIG. 7 shows an equivalent circuit model 700 for a mass-augmented PR, according to some embodiments. Similar to the BVD circuit model (FIG. 4), model 700 includes the PR's physical electrical input capacitance 702 (Cₚ) and an LCR branch including an inductor L 704, a capacitor C 406, and a resistor R 708 to model the PR's electromechanical resonance properties. However, in the case of a mass-augmented PR, a second inductor Lₘ 702 can be introduced to represent added inductance due to the mass layers, as shown.

### Changes to the Equivalent Electrical Circuit

By inserting (2) into (1), enforcing (5), and integrating to find vₚ and I_{L} the mass-augmented PR's impedance can be solved. After once again matching this impedance to the BVD circuit, it is found that the value of the inductor has increased. That larger inductor L can then be “split” between the original inductance of the non-augmented PR, and:

$${L}_{m} = 2 β \frac{{ρ}_{m}}{ρ} L \qquad ( 6 )$$

an additional inductance resulting from the added point mass, as represented by second inductor 710 in FIG. 7.

This “mass inductance” has the effect of shifting the entire impedance plot (and by extension the resonant and anti-resonant frequencies) downward.

FIG. 8 includes a plot 800 illustrating impedance shift due to mass augmentation of a PR, according to some embodiments. In more detail, a bare PR may have an inductive region 802 between a given resonant fᵣ frequency and anti-resonant frequency fₐᵣ, whereas a mass-augmented PR may have an inductive region 802 between a lower resonant fᵣ_{ₘ} frequency and a lower anti-resonant frequency fₐᵣ_{ₘ}, as shown.

The various plots shown and described herein (e.g., plot 800 of FIG. 8) are not intended to be limiting to the structures and techniques sought to be protected herein and are provided merely for illustrative purposes. In addition, dashed horizontal lines shown in the various plots indicate results that may be achieved for a non-augmented PR in contrast with results illustrated for mass-augmented PR's in the plots.

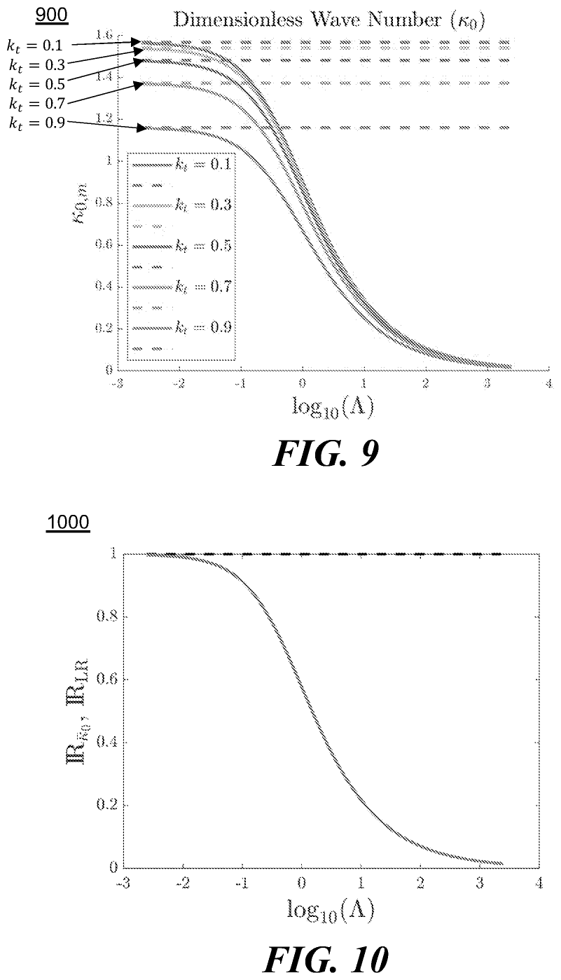

FIG. 9 demonstrates this downward shift, according to some embodiments. The operating frequency scales as:

$$\frac{{κ}_{0 , m}}{{\hat{κ}}_{0}} = \frac{1}{\sqrt{1 + 2 Λ}} , where Λ = β \frac{{ρ}_{m}}{ρ} \qquad ( 7 )$$

in which A, which is defined herein as the “mass factor”, represents the relative size of the added mass layer and is generally an independent variable (as shown in FIG. 9).

FIG. 9 shows a plot 900 of κ_{0,m} (not normalized by \hat{κ}₀), at different values of kₜ. The horizontal dashed lines represent \hat{κ}₀ for each respective kₜ value.

FIG. 10 is a plot of geometry-normalized wave number and loss ratio scaling as a function of mass factor, Λ, (defined in (7)) showing how a mass-augmented PR can scale the maximum-efficiency operating point, according to some embodiments.

### Effects of Augmentation on Figures of Merit

Above, it has been assumed that the added mass layer acts as a point mass and therefore that all losses occur in the piezoelectric material. This means that the value of R in FIGS. 4 and 7 remains the same. Because the mechanical efficiency FOM can be written as a function of R and Cₚ, both of which remain unaffected by the addition of mass layer(s), the form of FOM_{M} is also unchanged. However, because FOM_{M} is inversely related to the wave number at which the PR resonates, and as one increases Λ one operates the PR at a lower frequency, FOM_{M} increases with the following dependence on Λ:

$$\frac{{FOM}_{M , m}}{\hat{F} {OM}_{M}} = \sqrt{1 + 2 Λ} \qquad ( 8 )$$

Thus, mechanical efficiency increases monotonically with the size of the added mass.

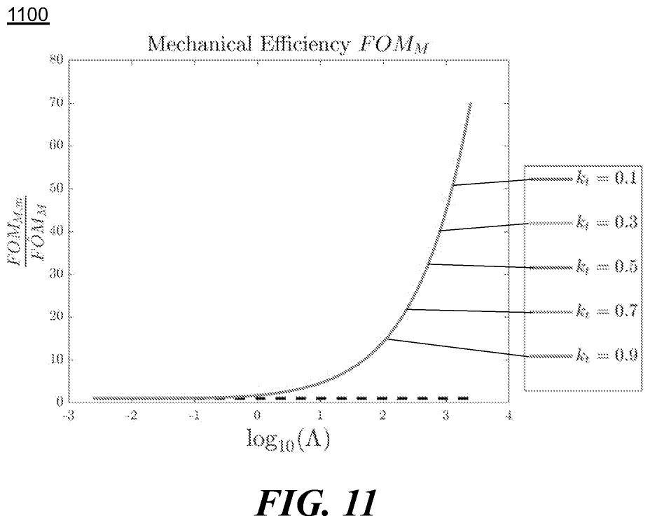

FIG. 11 shows a plot 1100 of FOM_{M}, m normalized by the non-augmented \hat{F}OM_{M}. As can be seen in the figure, all values of kₜ coincide.

### Geometry Normalized Maximum Current Amplitude

As discussed above, all losses in the model are described by the resistor R in FIG. 7. Because the value of R remains unchanged, the form of I_{L0,max}^{LD} remains unchanged. I_{L0,max}^{LD} also has no dependence on κ₀. As a result, I_{L0,max}^{LD} is a constant with respect to Λ.

I_{L0,max}^{T}, I_{L0,max}^{S}, and I_{L0,max}^{E} are all dependent on Λ. The effect of added mass is also dependent on the coupling factor, kₜ. That is:

$$\frac{{I}_{L 0 , max , m}^{T , S , E}}{{\hat{I}}_{L 0 , max}^{T , S , E}} = {f}_{T , S , E} ( Λ , {k}_{t} ) \qquad ( 9 )$$

Table 6 shows the functional forms of I_{L0,max,m}^{T}, I_{L0,max,m}^{S}, I_{L0,max,m}^{E}, and I_{L0,max,m}^{LD}.

TABLE 6
Geometry-Normalized Maximum Current Amplitudes

| I_{L0,max}^{T} | I_{L0,max}^{S} | I_{L0,max}^{E} |
|---|---|---|
| $\frac{{e}_{33} {v}_{a}}{{c}_{33}^{D}} \frac{sin ( {κ}_{0} )}{1 - cos {κ}_{0} + Λ {κ}_{0} sin ( {κ}_{0} )} {T}_{max}$ | e₃₃νₐsin(κ₀)Sₘₐₓ | ${k}_{t}^{2} {ϵ}_{33}^{S} \frac{sin ( κ l )}{cos ( {κ}_{0} ) - {k}_{t}^{2} - Λ {κ}_{0} sin ( {κ}_{0} )} {v}_{a} {E}_{max}$ |

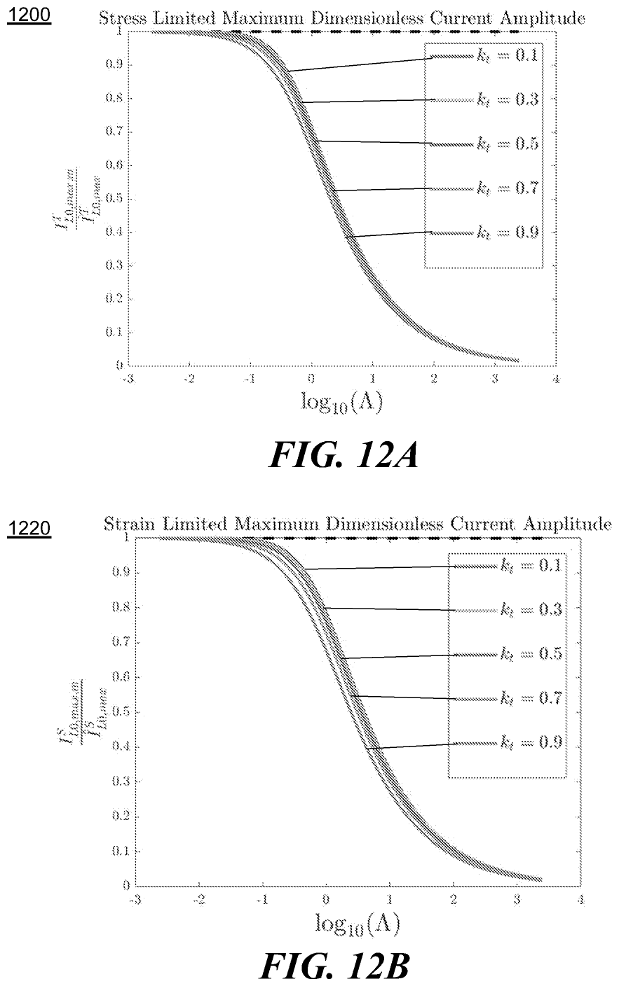

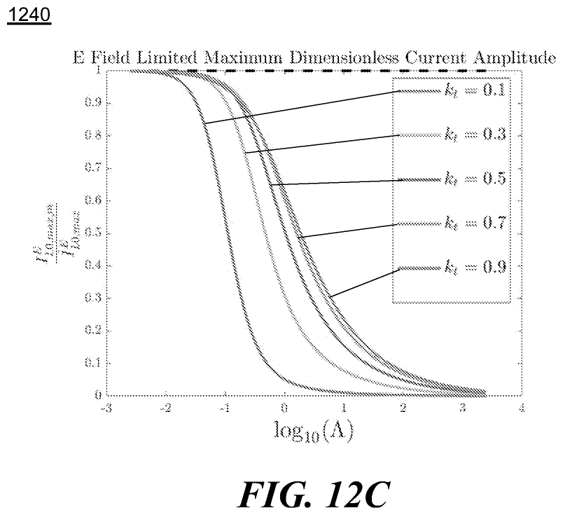

FIGS. 12A-12C show plots 1200, 1220, and 1240 of f_{T}(Λ, kₜ), f_{S}(Λ, kₜ), and f_{E} (Λ, kₜ), respectively, plotted against log₁₀(Λ) for different values of kₜ. For thickness extensional mode (and other parallel modes as described in PCT Pat. App. No. PCT/US2022/028043) f_{T,S,E}(Λ, kₜ) are all monotonically decreasing in A. In FIGS. 12A-12C, the different values of kₜ are shown using different line styles consistent with those used in FIG. 9.

Because I_{L0,max}^{LD} is generally lower than any other limiting condition for most practical cases, it is recognized herein that this presents an opportunity for power density improvement on the scale of multiple hundreds of percent. Eventually, as mass is added, one of the other current amplitude limits will reach I_{L0,max,m}^{T}, and this represents the maximum possible benefit from added mass (assuming one can still treat the mass as a point mass. A dimensionless parameter is derived below to determine whether this assumption is valid).

### Volumetric Energy Handling Density FOM

For the power FOMs, the loss-density-limited case gives great insight into the effect that increasing A has on the system (since I_{L0,max}^{LD} is independent of Λ and κ₀). The maximizations used to derive the form of the power FOMs may be independent of the state variable derivations and, thus, their form remains unchanged when mass is added except for including the additional volume of the added mass in FOM_{VEHD}. Because the denominator contains κ₀², and FOM_{VEHD} must now be divided by an additional 1+β, the following is true:

$$\frac{{FOM}_{VEHD , m}^{LD}}{\hat{F} {OM}_{VEHD}^{LD}} = \frac{1 + 2 Λ}{1 + β} = \frac{1 + 2 Λ}{1 + \frac{ρ}{{ρ}_{m}} Λ} {lim}_{Λ \to + ∞} ( \frac{{FOM}_{VEHD , m}^{LD}}{\hat{F} {OM}_{VEHD}^{LD}} ) = 2 \frac{{ρ}_{m}}{ρ} \qquad ( 10 )$$

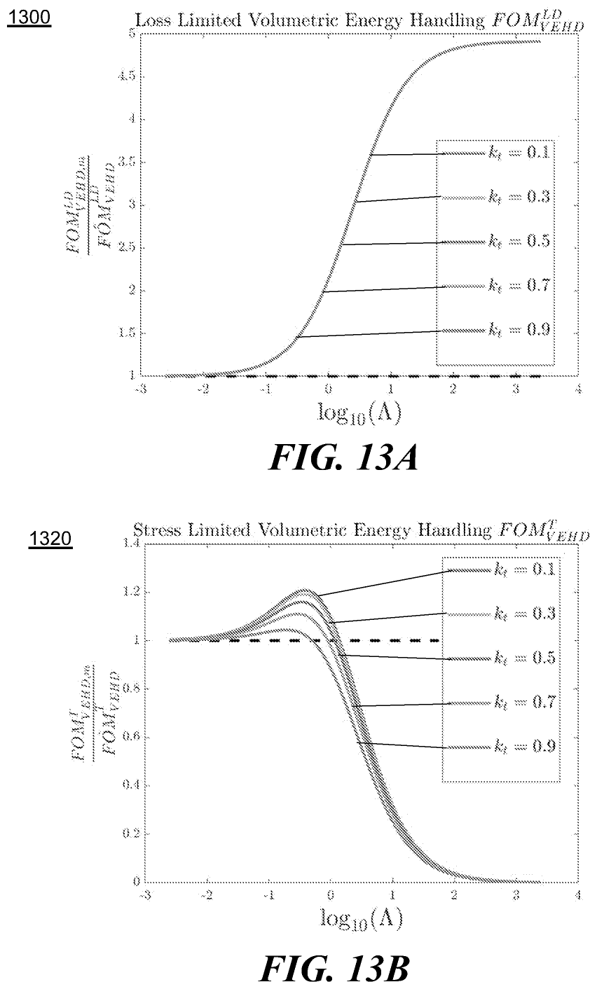

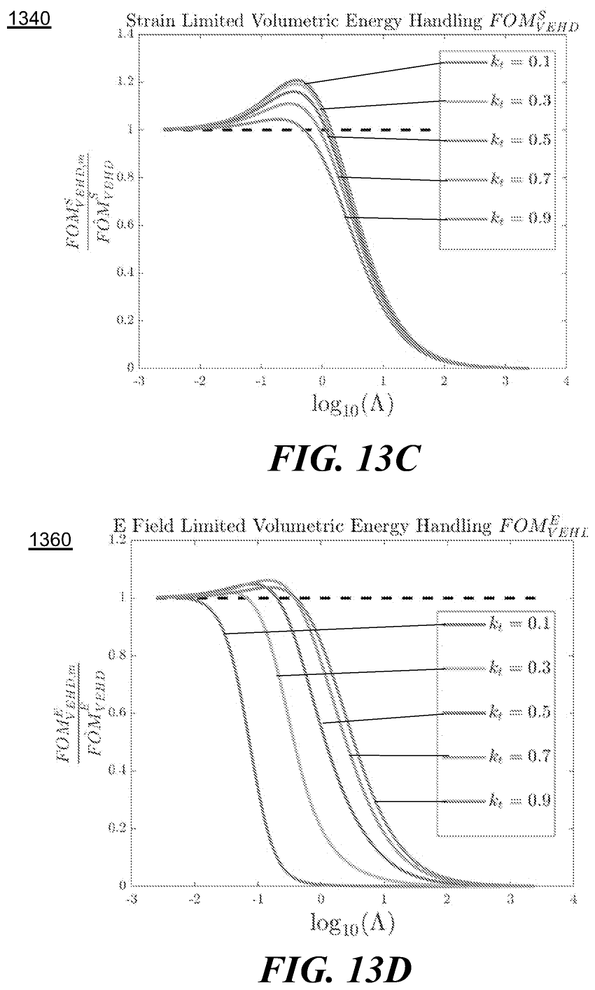

FIGS. 13A-13D include plots 1300, 1320, 1340, and 1360 of

$$\frac{{FOM}_{VEHD , m}^{LD}}{\hat{F} {OM}_{VEHD}^{LD}} , \frac{{FOM}_{VEHD , m}^{T}}{\hat{F} {OM}_{VEHD}^{T}} , \frac{{FOM}_{VEHD , m}^{S}}{\hat{F} {OM}_{VEHD}^{S}} , and \frac{{FOM}_{VEHD , m}^{E}}{\hat{F} {OM}_{VEHD}^{E}} ,$$

respectively, versus log₁₀(Λ). In FIGS. 13A-13D, the different values of kₜ are shown using different line styles consistent with those used in FIG. 9. In FIG. 13A, all values of kₜ coincide.

As shown in FIG. 13A, the loss limited volumetric energy handling density will increase monotonically towards a set limit. An important insight gained through (10) is that it may be desirable to make the mass layer out of as dense a material as possible (consistent with not introducing undue loss), as this will increase the slope of the central part of the curve of FIG. 13A and raise the upper limit of improvement.

For the stress, strain, and E-field limited cases, I_{L0,max} is no longer independent of Λ. In these cases, one finds:

$$\frac{{FOM}_{VEHD , m}^{T , S , E}}{\hat{F} {OM}_{VEHD}^{T , S , E}} = {f}_{T , S , E}^{2} ( Λ , {k}_{t} ) \frac{1 + 2 Λ}{1 + \frac{ρ}{{ρ}_{m}} Λ} \qquad ( 11 )$$

In general, for the stress, strain, and E-field limited cases, although FOM_{VEHD} (as shown in FIGS. 13A-13D) is not monotonically increasing, there is some benefit in an initial region, when the magnitude of decreasing κ₀ is greater than the losses from f_{T,S,E}(Λ, kₜ). This means that there is an ideal Λ for maximizing current when limited by stress, strain, or e-field. Two important notes. First, notice that for E field limited, the extreme values (highest or lowest) of kₜ do not necessarily show the best maximum percentage improvement for FOM_{VEHD} (and I_{L0,max} and FOM_{APD} for that matter). Second, for any of plots that have humps, although original FOM or I_{L0,max} may be low for a given kₜ compared to other values of kₜ improvement of that lower original value may lead to a higher maximum mass augmented non-normalized value.

### Areal Power Density FOM

In the case of the thickness extensional vibration mode (such as illustrated in the embodiment of FIG. 6), areal power density is independent of its thickness dimension, l. Therefore, unlike FOM_{VEHD}, FOM_{APD} does not need to be divided by an additional 1+β. As a result, the form of FOM_{APD} remains unchanged.

In the loss density limited case, because I_{L0,max}^{LD} is independent of Λ, changes in FOM_{APD} are completely dependent on the κ₀ in its denominator. This relationship is the same as for FOM_{M}, and thus:

$$\frac{{FOM}_{APD , m}^{LD}}{\hat{F} {OM}_{APD}^{LD}} = \sqrt{1 + 2 Λ} \qquad ( 12 )$$

FOM_{APD}^{LD} is also monotonically increasing.

In the stress (T), strain (S), and electric field (E) limited cases, I_{L0,max} is not independent of Λ. As a result, one finds

$$\frac{{FOM}_{APD , m}^{T , S , E}}{\hat{F} {OM}_{APD}^{T , S , E}} = {f}_{T , S , E}^{2} ( Λ , {k}_{t} ) \sqrt{1 + 2 Λ} \qquad ( 13 )$$

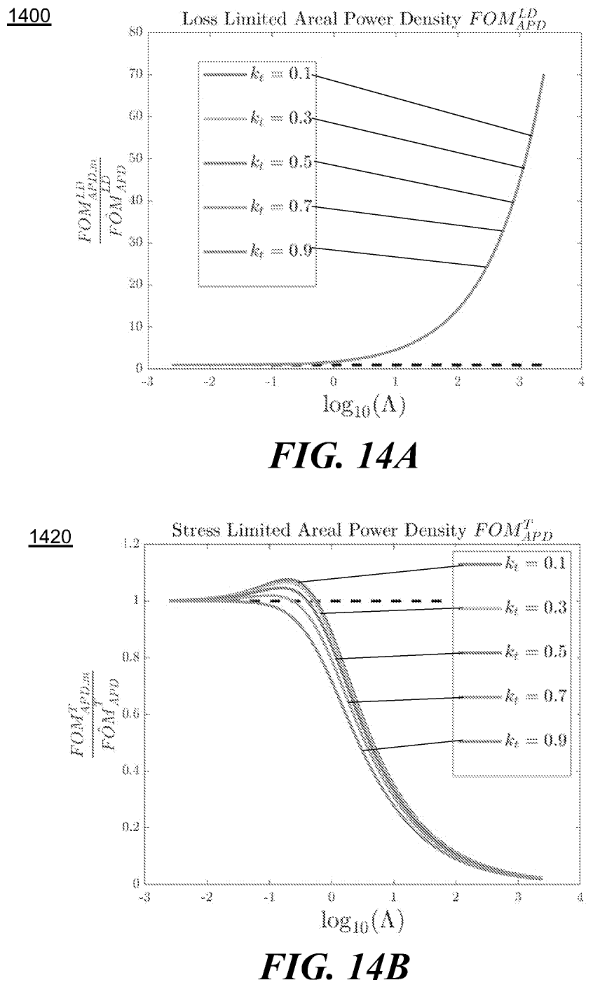

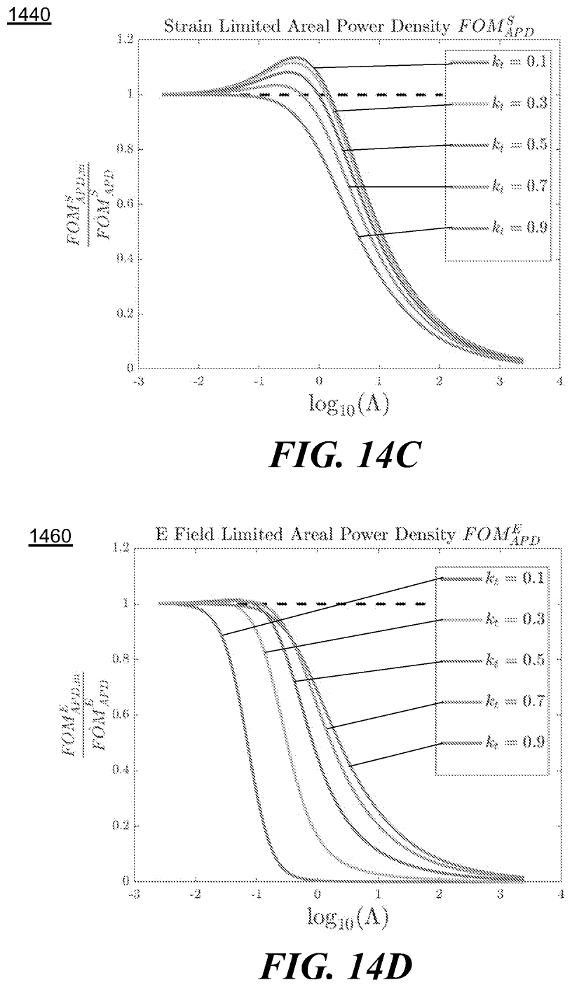

FIGS. 14A-14D include plots 1400, 1420, 1440, and 1460 of

$$\frac{{FOM}_{APD , m}^{LD}}{\hat{F} {OM}_{APD}^{LD}} , \frac{{FOM}_{APD , m}^{T}}{\hat{F} {OM}_{APD}^{T}} , \frac{{FOM}_{APD , m}^{S}}{\hat{F} {OM}_{APD}^{S}} , and \frac{{FOM}_{APD , m}^{E}}{\hat{F} {OM}_{APD}^{E}} ,$$

respectively, versus log₁₀(Λ). In FIGS. 14B-14D the different values of kₜ are shown using different line styles consistent with those used in FIG. 9. In FIG. 14A, all values of kₜ coincide.

As shown in FIGS. 14A-14D, similarly to FOM_{VEHD}, one finds that FOM_{APD}^{T,S,E} does not monotonically increase, and there is an ideal A for which FOM_{APD} is maximized.

### Design of a Composite Energy Storage Element Based on a Mass-Augmented Piezoelectric Resonator

It has now been shown that mass-augmented PRs forming a composite electromechanical energy storage component can operate with significantly higher power and energy densities than their non-augmented counterparts (i.e., a conventional piezoelectric resonator). This implies that it is possible to design a composite energy storage component that is functionally-equivalent to a PR for use in power conversion (serving the same voltage, current, and power levels) at a much smaller size. The design methodology described here will follow the same procedures outlined in in PCT Pat. App. No. PCT/US2022/028043.

In some embodiments, the PZT may be selected for use as a PR material, and Tungsten may be selected as a non-piezoelectric mass layer material, as it has a high stiffness and density when compared to PZT. It may be desirable to operate a mass-augmented PR, according to the present disclosure, at an input voltage of Vᵢₙ=100V and output power Pₒᵤₜ=10 W. To begin, the loss-limited case may be assumed (which may be true for in various practical applications). Assume a reasonable maximum loss density,

$${LD}_{max} = 1 \frac{W}{{cm}^{2}} .$$

l is selected implicitly through the power density FOMs which can both be maximized through the selection of a specific value for l. Similarly, the ratio 4ab/l² is selected through the minimization of the loss ratio. The resulting length and area ratio are:

$$l = {V}_{in} \frac{{κ}_{0} {v}_{a} {ϵ}_{33}^{S}}{2 {I}_{L 0 , max}^{LD}} \qquad ( 14 a )$$

$$\frac{4 ab}{{l}^{2}} = \frac{{P}_{out}}{{V}_{in}^{2}} \frac{4 π}{{κ}_{0} {v}_{a} {ϵ}_{33}^{S}} \qquad ( 14 b )$$

All but κ₀ is independent of Λ. Because κ₀ decreases with A it is evident that a larger mass factor (meaning a larger proportion of added mass to piezoelectric material mass) results in a thinner, more planar (4ab/l² increases) device.

According to some embodiments, an energy storage component can include a second attached material (e.g., one or more mass layers) configured to enable the converter to operate near one or more physical limits and, in some cases, near multiple physical limits. Such physical limits can include stress limits, strain limits, electric field limits, and/or loss density limits, which impose limits on I_{L0,max} for T, S, E, and/or LD (e.g., such as shown in Table 6). In more detail, the energy storage component can have geometric dimensions such that both conditions in (14a), (14b) are satisfied, assuming the minimum I_{L0,max} in (14a). Further, mass factor A can be selected such that this minimum I_{L0,max} is maximized to increase the energy storage component's power handling capability.

An important note is that there is a minimum total thickness (l+/βl) for the device that occurs at

$$β = 1 - \frac{ρ}{{ρ}_{m}} .$$

If the added material is as dense as or less dense than the original material (although the piezoelectric material layer is getting thinner), the overall thickness of the device increases. On the other hand, the electrode area, 4ab, decreases monotonically. Therefore, it may be desired to design for the thinnest possible device or to sacrifice device thickness and add additional mass to further decrease area.

For this design, β can be selected to be a value of about 0.35, because further augmentation will push beyond the point mass assumption made in (5). The described model can be improved by correcting for error introduced in an approximation for tangent during the derivation of our circuit parameters. In effect, one can multiply this approximation by a dimensionless constant ϕ which shifts the anti-resonant and resonant frequencies of the actual augmented PR, and circuit model to be roughly centered around the same frequency. In this case, one can choose ϕ=1.167. Table 7 details the resulting parameters of the design of a non-augmented PR (i.e., “bare” or “free” PR) and mass-augmented PRs, according to some embodiments.

TABLE 7
Mass-Augmented, LD Limited, Design Parameters

| | Free Case | | Mass-Augmented | | Ratio MA:F |
|---|---|---|---|---|---|
| PR Layer Thickness | 0.322 | mm | 0.184 | mm | 0.57 |
| Total Device Thickness | 0.322 | mm | 0.248 | mm | 0.77 |
| Electrode Area | 7.22 | mm² | 4.13 | mm² | 0.57 |
| Side Length (Square) | 2.6 | mm | 2 | mm | 0.76 |
| Volume | 2.33 | mm³ | 1.02 | mm³ | 0.44 |
| Mass | 18.2 | mg | 11.1 | mg | 0.61 |
| Operating Frequency | 6.8 | MHz | 6.8 | MHz | — |

$${V}_{in} = 100 V , {P}_{out} = 10 W , \frac{{ρ}_{m}}{ρ} = 2.46 , Λ = 0.86 , ϕ = 1.167$$

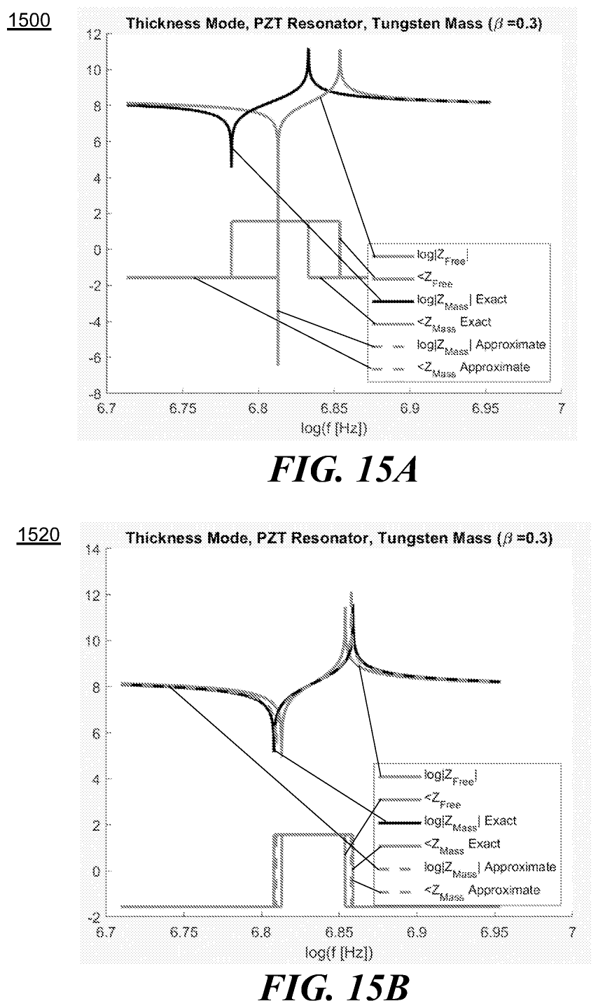

FIG. 15A shows an impedance plot 1500 of non-augmented (or “free”) PR and the approximated and non-approximated mass-augmented equivalent without ϕ (tangent approximation) correction. FIG. 15B shows an impedance plot 1520 of non-augmented (or “free”) PR and the approximated and non-approximated mass-augmented equivalent with ϕ (tangent approximation) correction. As can be seen, a mass-augmented PR according to the present disclosure may have substantially the same impedance as its non-augmented counterpart. In addition, disclosed mass-augmented PRs can satisfy all loss density requirements, and has identical efficiency. Decreases in total thickness, area, volume, and even total mass can be observed.

### Bi-Material Propagation Number

In derivations provided herein, one can assume the mass can be treated as a point mass (or that the spring can be treated as massless). Here, the validity of this assumption is quantified. For this, one can turn to dimensional analysis (although the same quantity can also be found through a lumped sum analysis or other similar methods).

The length of the layer is βl, and one can take x₃=0 to be at the center of the bare PR. For this derivation one can take the system to be the layer of mass attached to the PR from x₃=l to x₃=l+βl. Because it is assumed that this layer of material is pure elastic (not piezoelectric) the displacement must following wave equation:

$$\frac{{\partial }^{2} {u}_{3}}{\partial {t}^{2}} = {v}_{a , m}^{2} \frac{{\partial }^{2} {u}_{3}}{\partial {x}_{3}^{2}} \qquad ( 15 )$$

One can now non dimensionalize this equation through use of a time scale,

$$τ = \frac{1}{ω} = \frac{l}{{v}_{a} {κ}_{0}}$$

and length scale L̅=βl, where the non-dimensionalized variables become:

$${u}^{*} = \frac{{u}_{3} ( {x}_{3} , t )}{{u}_{3} ( {x}_{3} = l , t = 0 )} {x}^{*} = \frac{{x}_{3}}{β l} {t}^{*} = \frac{{v}_{a} {κ}_{0}}{l} t \qquad ( 16 )$$

The non dimensionalized wave equation is thus:

$$\frac{{\partial }^{2} {u}^{*}}{\partial {x}^{* 2}} - ( Wp ) \frac{{\partial }^{2} {u}^{*}}{\partial {t}^{* 2}} = 0 Wp = \frac{{v}_{a}^{2}}{{v}_{a , m}^{2}} {β}^{2} {κ}_{0}^{2} \qquad ( 17 )$$

where Wp is defined as the “Bi-Material Propagation Number.” τ and L̅ can be designed so that

$$\frac{{\partial }^{2} {u}^{*}}{\partial {x}^{* 2}} and \frac{{\partial }^{2} {u}^{*}}{\partial {t}^{* 2}}$$

must necessarily be of order O(1). If one takes a closer look at (17) this implies that if

$$Wp ≪ 1 , \frac{{\partial }^{2} {u}_{3}}{\partial {x}_{3}^{2}} \approx 0 ,$$

which in turn implies the form:

$${u}_{3} = {Ax}_{3} + B \qquad ( 18 )$$

Once one applies the boundary conditions:

$${u}_{3} ( {x}_{3} = l , 0 ) = Δsin ( {κ}_{0} ) {e}^{j ω t} {T}_{3} ( {x}_{3} = l + β l ) = {Y}_{m} \frac{\partial {u}_{3}}{\partial {x}_{3}} ( {x}_{3} = l + β l ) = 0 \qquad ( 19 )$$

The equation for a point mass can be recovered:

$${u}_{3} ( {x}_{3} , t ) = Δsin ( {κ}_{0} ) {e}^{j ω t} l < {x}_{3} < l + β l \qquad ( 20 )$$

Thus, the condition for treating a mass layer, according to disclosed embodiments, as a point mass is Wp<<1.

It is also important to note that for a Mass-Augmented System, Wp can be written as:

$$Wp = \frac{ρ}{{ρ}_{m}} \frac{{c}^{D} 33}{{Y}_{m}} \frac{{Λ}^{2}}{1 + 2 Λ} {\hat{κ}}_{0}^{2} \qquad ( 21 )$$

where \hat{κ}₀ is the non-augmented dimensionless wave number and Yₘ is the Young's Modulus of the added mass. From this, it can be seen that as one increases the relative size of the mass layer, decreases its relative stiffness, or decreases its relative density, the point mass assumption may begin to break down. Thus, at this point, it may be necessary to consider additional effects such as loss due to wave propagation through the mass layer as part of the composite component design.

As used herein, the terms “processor” and “controller” are used to describe electronic circuitry that performs a function, an operation, or a sequence of operations. The function, operation, or sequence of operations can be hard coded into the electronic circuit or soft coded by way of instructions held in a memory device. The function, operation, or sequence of operations can be performed using digital values or using analog signals. In some embodiments, the processor or controller can be embodied in an application specific integrated circuit (ASIC), which can be an analog ASIC or a digital ASIC, in a microprocessor with associated program memory and/or in a discrete electronic circuit, which can be analog or digital. A processor or controller can contain internal processors or modules that perform portions of the function, operation, or sequence of operations. Similarly, a module can contain internal processors or internal modules that perform portions of the function, operation, or sequence of operations of the module.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

In the foregoing detailed description, various features are grouped together in one or more individual embodiments for the purpose of streamlining the disclosure. This method of disclosure is not to be interpreted as reflecting an intention that each claim requires more features than are expressly recited therein. Rather, inventive aspects may lie in less than all features of each disclosed embodiment.

References in the disclosure to “one embodiment,” “an embodiment,” “some embodiments,” or variants of such phrases indicate that the embodiment(s) described can include a particular feature, structure, or characteristic, but every embodiment can include the particular feature, structure, or characteristic. Moreover, such phrases are not necessarily referring to the same embodiment(s). Further, when a particular feature, structure, or characteristic is described in connection knowledge of one skilled in the art to affect such feature, structure, or characteristic in connection with other embodiments whether or not explicitly described.

The disclosed subject matter is not limited in its application to the details of construction and to the arrangements of the components set forth in the following description or illustrated in the drawings. The disclosed subject matter is capable of other embodiments and of being practiced and carried out in various ways. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

All publications and references cited herein are expressly incorporated herein by reference in their entirety.

1. An electrical-to-electrical power converter comprising:
an energy storage component including a transducer material and a second material for mechanical energy storage, the second material attached to the transducer material.

2. The converter of claim 1, wherein the energy storage component is an electromechanical resonator.

3. The converter of claim 1, wherein the transducer material has electrodes coupled to one or more of its surfaces.

4. The converter of claim 3, wherein the second material is attached at least one of the more surfaces to which the electrodes are coupled.

5. The converter of claim 4, wherein the second material is attached to one or more surfaces of the transducer material different from the one or more surfaces to which the electrodes are coupled.

6. The converter of claim 1, wherein the energy storage component is a single-port device.

7. The converter of claim 1, wherein the energy storage component is a multi-port device.

8. The converter of claim 1, wherein the transducer material includes a piezoelectric material.

9. The converter of claim 1, wherein the transducer material and the second material are both configured to store mechanical energy.

10. The converter of claim 9, where the mechanical energy stored by the second material is at least 10% of total mechanical energy stored by the energy storage component.

11. The converter of claim 9, wherein the mechanical energy stored by the second material is primarily kinetic energy.

12. The converter of claim 1, wherein the second material comprises a high-mass-density material.

13. The converter of claim 12, wherein the high-mass-density material includes at least one of: tungsten, gold, platinum, lead, or uranium.

14. The converter of claim 1, wherein the second material is configured to enable the converter to operate near one or more physical limits.

15. The converter of claim 14, wherein the physical limits include stress limits, strain limits, electric field limits, and loss density limits.

16. The converter of claim 1, wherein the second material has a volume which is greater than or equal to a volume of the transducer material.

17. The converter of claim 1, wherein the second material has a volume which is less than a volume of the transducer material.

18. The converter of claim 1, wherein all or part of the second material has a density greater than or equal to that of the transducer material.

19. The converter of claim 1, wherein the second material includes multiple distributed layers.

20. The converter of claim 19, wherein the multiple distributed layers of the second material have substantially identical geometries and material compositions.

21. The converter of claim 1, wherein the second material includes a patterned material structure comprising a mesh pattern or a backbone-and-rib pattern.

22. The converter of claim 1, wherein all or part of the second material spans an entire surface of the transducer material.

23. The converter of claim 1, wherein the second material is attached to one or more electrodes of the transducer material.

24. The converter of claim 1, wherein all or part of the second material may be electrically insulative.

25. The converter of claim 1, wherein the second material is configured to provide an acoustic wave boundary.

26. The converter of claim 1, wherein the transducer material has first and second electrodes on first and second opposing planar surfaces of the transducer material.

27. The converter of claim 26, wherein the second material includes a first mass layer attached to the first electrode.

28. The converter of claim 27, wherein the second material includes a second mass layer attached to the second electrode.

29. The converter of claim 28, wherein the transducer material, the first mass layer, and the second mass layer are all configured to store mechanical energy during operation of the converter.

30. The converter of claim 29, wherein the transducer material includes a piezoelectric resonator (PR).

31. The converter of claim 1, wherein the transducer material is configured to have a length extensional vibration mode.

32. The converter of claim 1, wherein the transducer material is configured to have a thickness shear vibration mode.

33. The converter of claim 1, wherein the transducer material is configured to have a thickness extensional vibration mode.

34. The converter of claim 1, wherein the transducer material is configured to have a contour extensional vibration mode.

35. The converter of claim 1, wherein the transducer material is configured to have a radial vibration mode.

36. The converter of claim 1, wherein the transducer material has at least four surfaces with electrodes coupled to two of the at least four surfaces.

37. The converter of claim 36, wherein the second material is attached to at least one of the at least four surfaces to which the electrodes are coupled.

38. The converter of claim 36, wherein the second material is attached to at least one of the at least four surfaces different from those to which the electrodes are coupled.

39. An energy storage component for a power converter, the energy storage component comprising:
a piezoelectric resonator (PR) having first and second electrodes on first and second opposing planar surfaces of the PR;
a first mass layer attached to the first electrode; and
a second mass layer attached to the second electrode,
wherein the PR, the first mass layer, and the second mass layer are all configured to store mechanical energy during operation of the PR.

40. The energy storage component of claim 39, wherein the PR is configured to have a thickness extensional vibration mode.

41. A power converter having an input and an output, the converter comprising:
an energy storage component including a transducer material and a second material attached thereto, the transducer material and the second material both being configured to store mechanical energy; and
a plurality of switches configured to transfer energy from the converter input to the converter output via the energy storage component.
